(19) United States
(12) Patent Application Publication
(10) Pub. No.: US 2025/0309613 A1
(43) Pub. Date: Oct. 2, 2025

(54) LASER MODULE

(71) Applicant: NEC Corporation, Tokyo (JP)

(72) Inventor: Motoyoshi KAWAI, Tokyo (JP)

(73) Assignee: NEC Corporation, Tokyo (JP)

(21) Appl. No.: 18/967,778

(22) Filed: Dec. 4, 2024

(30) Foreign Application Priority Data
Mar. 27, 2024 (JP) 2024-050637

(51) Int. Cl. H01S 5/068; H02M 3/02

(52) U.S. Cl. CPC H01S 5/06808; H02M 3/02

(57) ABSTRACT

The present disclosure provides a laser module including: a first excitation laser module; a first DC/DC converter including a first terminal connected to a first terminal of the first excitation laser module, and a second terminal connected to a second terminal of the first excitation laser module; a second excitation laser module including a first terminal connected to the second terminal of the first excitation laser module; a second DC/DC converter including a first terminal connected to the first terminal of the second excitation laser module, and a second terminal connected to a second terminal of the second excitation laser module; a control circuit connected to the first DC/DC converter and the second DC/DC converter; and a Zener diode connected to the first DC/DC converter and the second DC/DC converter.

### INCORPORATION BY REFERENCE

This application is based upon and claims the benefit of priority from Japanese patent application No. 2024-50637, filed on Mar. 27, 2024, the disclosure of which is incorporated herein in its entirety by reference.

### TECHNICAL FIELD

The present disclosure relates to a laser module.

### BACKGROUND ART

Patent Literature 1 discloses a laser module including a DC/DC converter that inputs a predetermined voltage and outputs it to a load in order to supply a predetermined current to each of a plurality of loads in a case where a constant current is supplied to one power source line. The laser module comprises a current control circuit having a voltage dividing resistor that generates a reference voltage in accordance with a voltage output from the DC/DC converter and a current detecting resistor that generates a current detecting voltage in accordance with the current flowing through the load. Further, the current control circuit includes a feedback circuit that compares the reference voltage with the current detecting voltage and outputs a control signal indicating a comparison result to the DC/DC converter. The laser module includes a plurality of circuit elements including one or more Zener diodes connected in parallel at terminals that input a predetermined voltage to each DC/DC converter. Further, in the laser module, the plurality of circuit elements are connected in series with each other, and a system current is supplied from an external power source to the plurality of circuit elements connected in series with each other.

Patent Literature 1: International Patent Publication No. WO 2022/158311

However, in the laser module disclosed in Patent Literature 1, since Zener diodes are connected in parallel to the respective DC/DC converters, the respective outputs of the DC/DC converters cannot be individually adjusted, and thus only constant control at a predetermined voltage value can be performed. Therefore, an object of the present disclosure is to provide a laser module capable of adjusting the respective outputs of a plurality of DC/DC converters.

### SUMMARY

A laser module capable of adjusting the respective outputs of a plurality of DC/DC converters is provided.

A laser module according to a first example aspect of the present disclosure includes:
a first excitation laser module including a first terminal and a second terminal;
a first DC/DC converter including a first terminal connected to the first terminal of the first excitation laser module, and a second terminal connected to the second terminal of the first excitation laser module;
a second excitation laser module including a first terminal connected to the second terminal of the first excitation laser module, and a second terminal;
a second DC/DC converter including a first terminal connected to the first terminal of the second excitation laser module, and a second terminal connected to the second terminal of the second excitation laser module;
a control circuit connected to the first DC/DC converter and the second DC/DC converter; and
a Zener diode connected to the first DC/DC converter and the second DC/DC converter.

A laser module according to a second example aspect of the present disclosure includes:
a set of n excitation laser modules and n DC/DC converters, where n is a natural number greater than or equal to two;
a control circuit connected to the n DC/DC converters; and
a Zener diode connected to the n DC/DC converters,
in which the set of the n excitation laser modules and the n DC/DC converters is disposed so that a first terminal of the k-th excitation laser module is connected to a first terminal of the k-th DC/DC converter and a second terminal of the k-th excitation laser module is connected to a second terminal of the k-th DC/DC converter, where k is a natural number from one to n.

### BRIEF DESCRIPTION OF DRAWINGS

The above and other aspects, features and advantages of the present disclosure will become more apparent from the following description of certain example embodiments when taken in conjunction with the accompanying drawings, in which:

FIG. 1 is a circuit diagram of a laser module according to the present disclosure; and

FIG. 2 is a circuit diagram of a related laser module.

### EXAMPLE EMBODIMENT

### Example Embodiment

A laser module according to an example embodiment is an excitation laser module that supplies excitation light to an erbium-doped fiber for amplifying light in a submarine optical repeater applied to a large-capacity submarine communication system. The laser module includes a DC/DC converter in each excitation laser module, whereby it is possible to supply, to an optical amplifier pair, a current having a magnitude greater than or equal to that of the current supplied from a land station, increase the output of excitation light, and achieve a high output or multi-core of a submarine repeater.

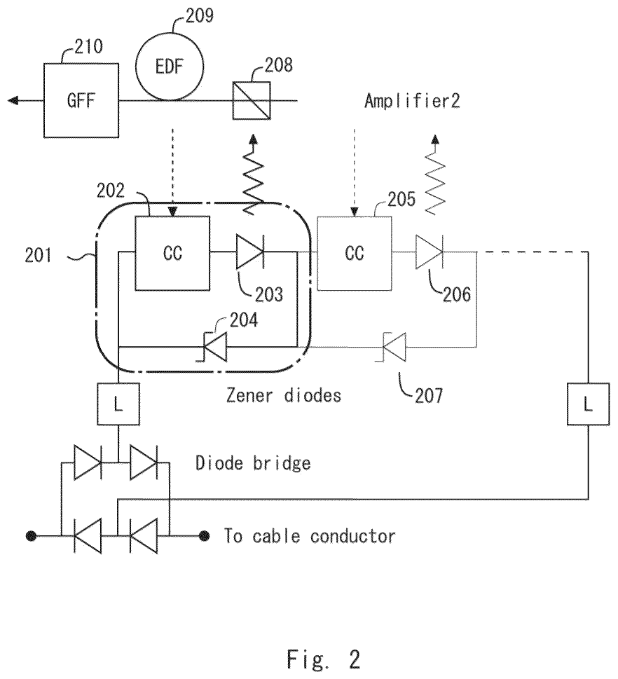

A related laser module will be described with reference to FIG. 2. Dense Wavelength Division Multiplexing (DWDM) systems are often applied to communication networks laid on the bottom of the sea. In a submarine optical repeater used in a communication network, an optical amplifier using an erbium-doped fiber is used to amplify an attenuated optical signal to an appropriate level.

As shown in FIG. 2, a related laser module 200 adjusts the currents of excitation laser modules 203 and 206 using current control circuits 202 and 205 and Zener diodes 204 and 207, and supplies the excitation lights through an optical coupler 208 to an erbium-doped fiber (EDF) 209 installed in an up-and-down direction of a fiber pair. An optical signal light is amplified by the EDF 209, incident on a gain flattening module (Gain Flattening Filer (GFF)) 210, and emitted.

At present, in a submarine communication network, it is necessary to increase the output of a submarine optical repeater and increase the number of fiber pairs in order to expand a transmission capacity, and therefore it is necessary to increase the output of the excitation laser module.

However, in the configuration shown in FIG. 2, there is a problem that the magnitude of current that can be made to flow through an excitation laser module 201 cannot be made greater than that of the current (To Cable Conductor) supplied from the power supply (Power Feeding Equipment (PFE)) of a land terminal station. In order to solve this problem, a method for increasing the supply current of the power supply set on land or a method for increasing the number of excitation laser modules shown in FIG. 2 from, for example, two to four is used.

In the first solution, the upper current limit of the currently commonly used PFE is 1.3 A, which is short of the current (to 1.8 A) allowed for a high-power excitation laser module.

Further, in a case where the number of excitation laser modules is increased, which is the second solution, a method for controlling the excitation laser modules in the optical amplifier pair becomes complicated. The number of couplers that multiplex excitation light increases, and thus a method for distributing the excitation light to erbium-doped fibers becomes complicated, and the size of the device is also increased. Further, it becomes difficult to select excitation laser modules having the same current-optical characteristics, and the manufacturing of a submarine optical repeater becomes difficult.

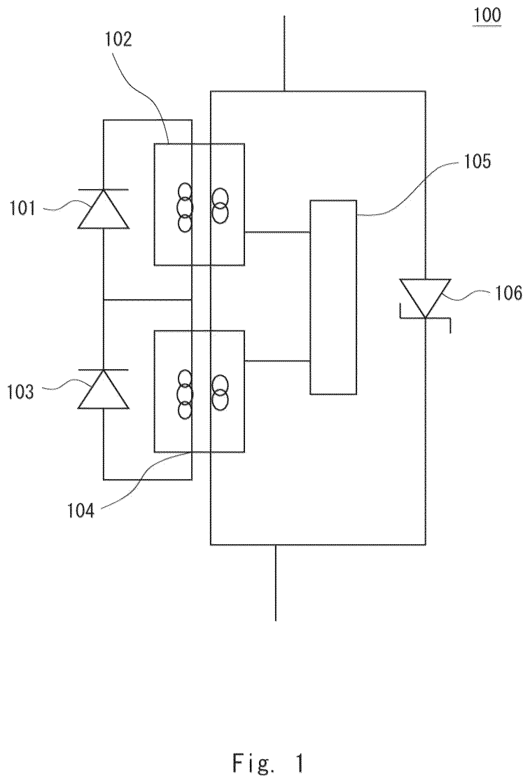

An example of a configuration of a laser module 100 will be described below with reference to FIG. 1. As shown in FIG. 1, the laser module 100 includes a first excitation laser module 101, a first DC/DC converter 102, a second excitation laser module 103, a second DC/DC converter 104, a control circuit 105, and a Zener diode 106.

The first excitation laser module 101 uses a semiconductor laser that oscillates near-infrared light having a wavelength of, for example, 1.48 μm or 0.98 μm. That is, the first excitation laser module is represented on the circuit as a diode and represented by a load. The first excitation laser module 101 includes a negative first terminal and a positive second terminal.

The first DC/DC converter 102 is provided in order to make a current having a magnitude greater than or equal to that of the current supplied from the power supply flow through the first excitation laser module 101. Therefore, the first DC/DC converter 102 includes a negative first terminal connected to the first terminal of the first excitation laser module and a positive second terminal connected to the second terminal of the first excitation laser module.

The second excitation laser module 103 can use the same semiconductor laser as that used in the first excitation laser module 101. The second excitation laser module 103 includes a negative first terminal connected to the second terminal of the first excitation laser module 101 and a positive second terminal.

The second DC/DC converter 104 is provided in order to make a current having a magnitude greater than or equal to that of the current supplied from the power supply flow through the second excitation laser module 103. Therefore, the second DC/DC converter 104 includes a negative first terminal connected to the first terminal of the second excitation laser module 103 and a positive second terminal connected to the second terminal of the second excitation laser module 103.

The control circuit 105 independently controls the first DC/DC converter 102 and the second DC/DC converter 104. Therefore, the control circuit 105 is connected to both the first DC/DC converter 102 and the second DC/DC converter 104.

The Zener diode 106 is connected in series with the first DC/DC converter 102 and the second DC/DC converter 104. The Zener diode 106 makes voltages applied to the first DC/DC converter 102 and the second DC/DC converter 104 connected in series with each other constant. Therefore, the first DC/DC converter 102 and the second DC/DC converter 104 are independently controlled, and the first excitation laser module 101 and the second excitation laser module 103 are independently output.

In a case where there are two excitation laser modules, a fourth terminal of the first DC/DC converter 102 is connected to a third terminal of the second DC/DC converter 104, and a fourth terminal of the second DC/DC converter 104 is connected to a first terminal of the Zener diode 106. Further, a second terminal of the Zener diode 106 is connected to a third terminal of the first DC/DC converter 102.

Further, in a case where there are two excitation laser modules, the fourth terminal of the second DC/DC converter 104 and the first terminal of the Zener diode 106 are connected to a power supply voltage, and the third terminal of the first DC/DC converter 102 and the second terminal of the Zener diode 106 are connected to a ground voltage.

In a case where there are n (n is a natural number greater than or equal to two) excitation laser modules and they are paired with n DC/DC converters, the control circuit is connected to each of the n DC/DC converters. Further, the Zener diodes are connected in series with the n DC/DC converters.

Further, a negative first terminal of the k-th (k is a natural number from one to n) excitation laser module is connected to a negative first terminal of the k-th DC/DC converter, and a positive second terminal of the k-th excitation laser module is connected to a positive second terminal of the k-th DC/DC converter. In this way, a set of n excitation laser modules and n DC/DC converters is disposed.

In this case, a fourth terminal of the l-th (l is a natural number from one to n−1) DC/DC converter is connected to a third terminal of the l+1-th DC/DC converter. A fourth terminal of the n-th DC/DC converter is connected to the first terminal of the Zener diode. Further, the second terminal of the Zener diode is connected to a third terminal of the first DC/DC converter.

Further, in this case, the fourth terminal of the n-th DC/DC converter and the first terminal of the Zener diode are connected to the power supply voltage, and the third terminal of the first DC/DC converter and the second terminal of the Zener diode are connected to the ground voltage.

As described above, two or more excitation laser modules may be arranged in series to obtain amplified laser light.

The current supplied from the land station is increased by a DC/DC converter having a one-to-one relationship with the excitation laser module inside the optical amplifier pair. The output of the excitation laser module constituting the optical amplifier pair is increased to a required level. At this time, the current of each excitation laser module can be adjusted by a control circuit.

The upper limit of the current supplied to the excitation laser module of the related laser module is the current of the Cable Conductor supplied from the power supply of the land station. In the laser module according to the present disclosure, by attaching a DC/DC converter to each excitation laser module of the optical amplifier pair, a current having a magnitude greater than or equal to that of the current supplied from the Cable Conductor can be made to flow, and a current capable of increasing the output of the excitation laser module can be supplied.

Further, in the optical amplifier pair, only a DC/DC converter is added, and the number of excitation laser modules does not need to be increased. Therefore, the number of excitation laser modules does not need to be changed from two. Since the control circuit adjusts the optical output of each excitation laser module, it is not necessary to select excitation laser modules that align the optical outputs for the same current. Further, it is not necessary to change the distribution of the excitation light to the erbium-doped fiber due to the addition of an optical coupler which is required in a case where the number of excitation laser modules is increased.

Therefore, the output of the submarine optical repeater and the output of the optical amplifier pair can be increased.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment can be appropriately combined with at least one of example embodiments.

Each of the drawings or figures is merely an example to illustrate one or more example embodiments. Each figure may not be associated with only one particular example embodiment, but may be associated with one or more other example embodiments. As those of ordinary skill in the art will understand, various features or steps described with reference to any one of the figures can be combined with features or steps illustrated in one or more other figures, for example, to produce example embodiments that are not explicitly illustrated or described. Not all of the features or steps illustrated in any one of the figures to describe an example embodiment are necessarily essential, and some features or steps may be omitted. The order of the steps described in any of the figures may be changed as appropriate.

The whole or part of the example embodiments disclosed above can be described as, but not limited to, the following supplementary notes.

### Supplementary Note 1

A laser module comprising:
a first excitation laser module comprising a first terminal and a second terminal;
a first DC/DC converter comprising a first terminal connected to the first terminal of the first excitation laser module, and a second terminal connected to the second terminal of the first excitation laser module;
a second excitation laser module comprising a first terminal connected to the second terminal of the first excitation laser module, and a second terminal;
a second DC/DC converter comprising a first terminal connected to the first terminal of the second excitation laser module, and a second terminal connected to the second terminal of the second excitation laser module;
a control circuit connected to the first DC/DC converter and the second DC/DC converter; and
a Zener diode connected to the first DC/DC converter and the second DC/DC converter.

### Supplementary Note 2

The laser module according to supplementary note 1, wherein
a fourth terminal of the first DC/DC converter is connected to a third terminal of the second DC/DC converter,
a fourth terminal of the second DC/DC converter is connected to a first terminal of the Zener diode, and
a second terminal of the Zener diode is connected to a third terminal of the first DC/DC converter.

### Supplementary Note 3

The laser module according to supplementary note 1, wherein
the fourth terminal of the second DC/DC converter and the first terminal of the Zener diode are connected to a power supply voltage, and
the third terminal of the first DC/DC converter and the second terminal of the Zener diode are connected to a ground voltage.

### Supplementary Note 4

A laser module comprising:
a set of n excitation laser modules and n DC/DC converters, where n is a natural number greater than or equal to two;
a control circuit connected to the n DC/DC converters; and
a Zener diode connected to the n DC/DC converters,
wherein the set of the n excitation laser modules and the n DC/DC converters is disposed so that a first terminal of the k-th excitation laser module is connected to a first terminal of the k-th DC/DC converter and a second terminal of the k-th excitation laser module is connected to a second terminal of the k-th DC/DC converter, where k is a natural number from one to n.

### Supplementary Note 5

The laser module according to supplementary note 4, wherein
a fourth terminal of the l-th DC/DC converter is connected to a third terminal of the l+1-th DC/DC converter, where l is a natural number from one to n−1,
a fourth terminal of the n-th DC/DC converter is connected to a first terminal of the Zener diode, and
a second terminal of the Zener diode is connected to a third terminal of the first DC/DC converter.

### Supplementary Note 6

The laser module according to supplementary note 4, wherein
the fourth terminal of the n-th DC/DC converter and the first terminal of the Zener diode are connected to a power supply voltage, and
the third terminal of the first DC/DC converter and the second terminal of the Zener diode are connected to a ground voltage.

The present disclosure provides a laser module capable of adjusting the respective outputs of a plurality of DC/DC converters.

While the disclosure has been particularly shown and described with reference to example embodiments thereof, the disclosure is not limited to these example embodiments. It will be understood by those of ordinary skill in the art that various changes in form and details may be made therein without departing from the spirit and scope of the present disclosure as defined by the claims.

What is claimed is:

1. A laser module comprising:
a first excitation laser module comprising a first terminal and a second terminal;
a first DC/DC converter comprising a first terminal connected to the first terminal of the first excitation laser module, and a second terminal connected to the second terminal of the first excitation laser module;
a second excitation laser module comprising a first terminal connected to the second terminal of the first excitation laser module, and a second terminal;
a second DC/DC converter comprising a first terminal connected to the first terminal of the second excitation laser module, and a second terminal connected to the second terminal of the second excitation laser module;
a control circuit connected to the first DC/DC converter and the second DC/DC converter; and
a Zener diode connected to the first DC/DC converter and the second DC/DC converter.

2. The laser module according to claim 1, wherein
a fourth terminal of the first DC/DC converter is connected to a third terminal of the second DC/DC converter,
a fourth terminal of the second DC/DC converter is connected to a first terminal of the Zener diode, and
a second terminal of the Zener diode is connected to a third terminal of the first DC/DC converter.

3. The laser module according to claim 1, wherein
the fourth terminal of the second DC/DC converter and the first terminal of the Zener diode are connected to a power supply voltage, and
the third terminal of the first DC/DC converter and the second terminal of the Zener diode are connected to a ground voltage.

4. A laser module comprising:
a set of n excitation laser modules and n DC/DC converters, where n is a natural number greater than or equal to two;
a control circuit connected to the n DC/DC converters; and
a Zener diode connected to the n DC/DC converters,
wherein the set of the n excitation laser modules and the n DC/DC converters is disposed so that a first terminal of the k-th excitation laser module is connected to a first terminal of the k-th DC/DC converter and a second terminal of the k-th excitation laser module is connected to a second terminal of the k-th DC/DC converter, where k is a natural number from one to n.

5. The laser module according to claim 4, wherein
a fourth terminal of the l-th DC/DC converter is connected to a third terminal of the l+1-th DC/DC converter, where I is a natural number from one to n-1,
a fourth terminal of the n-th DC/DC converter is connected to a first terminal of the Zener diode, and
a second terminal of the Zener diode is connected to a third terminal of the first DC/DC converter.

6. The laser module according to claim 4, wherein
the fourth terminal of the n-th DC/DC converter and the first terminal of the Zener diode are connected to a power supply voltage, and
the third terminal of the first DC/DC converter and the second terminal of the Zener diode are connected to a ground voltage.
